(19) United States
(12) Patent Application Publication
(10) Pub. No.: US 2006/0046434 A1
(43) Pub. Date: Mar. 2, 2006

(54) Method for reducing lead precipitation during wafer processing

(75) Inventors: Boe Su, Chiayi City (TW); H.M. Yu, HsinChu (TW); Chia-Jen Cheng, Taoyuan City (TW); Tzu-Han Lin, Hsin-Chu (TW); Kuo-Wei Lin, Shinchu County (TW)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: Taiwan Semiconductor Manufacturing Company, Ltd.

(21) Appl. No.: 10/926,764

(22) Filed: Aug. 26, 2004

(51) Int. Cl. H01L 21/78; H01L 21/44; H01L 21/302

(52) U.S. Cl. 438/460; 438/613; 438/754

(57) ABSTRACT

A method for preventing lead precipitation during wafer processing is disclosed. The method includes singulating a semiconductor wafer having a plurality of solder bumps and applying cold deionized (DI) water to the semiconductor wafer during singulation. Application of the cold DI water reduces or prevents lead precipitation during the singulation process, and thereby reduces the presence of bump oxidation.

### TECHNICAL FIELD

Disclosed embodiments herein relate generally to semiconductor wafer processing, and more particularly to a method for reducing or preventing Pb (“lead”) precipitation during such processing.

### BACKGROUND

Semiconductor wafer processes generally begin with processes associated with fabricating a semiconductor wafer such as layering, patterning, doping, and heat treatments. Once fabricated, semiconductor wafers undergo additional processes associated with testing, packaging, and assembling semiconductor chips obtained from the wafers. Semiconductor manufacturing processes are continually being refined, modified, and improved in light of breakthroughs in semiconductor technology. One such technology that has continued to gain increased acceptance is “flip chip” technology, which refers to microelectronic assemblies in which direct electrical connections between face down, or flipped, chip components and substrates are achieved through conductive bump pads formed on the chip.

Flip chips are manufactured to include solder bumps, which are formed on electrode pads of such chips to physically and electronically connect the electrode pads with electrode terminals provided on packaging such as ceramic substrates, printed circuit boards, or carriers. Solder bumps are typically formed of a metal alloy such as a lead-tin alloy, and are often applied to semiconductor wafers prior to separation into individual semiconductor chips.

Various separation, or singulation, processes have been developed to cut semiconductor wafers into individual semiconductor chips, which generally constitute entire integrated circuits. For example, die-saw processes are often used to cut wafers along cut, or scribe, lines used to demarcate chips on a wafer.

Water cleaning processes are additionally performed on the wafers and individual chips before, during and/or after the die-saw process. It has been found that water cleaning tends to cause lead precipitation, especially in solder having a high lead content. Lead precipitation generally involves the separation of lead from the solder during the water cleaning processes. Once a wafer and its associated chips become dry, the precipitated lead typically re-crystallizes as residue on the wafer surface. Lead precipitation leads to solder bump oxidation, which can be problematic due to increased resistance through the solder bump and decreased adhesive strength. Moreover, disposal of spent electrical devices having varying amounts of lead residue can be detrimental to the environment.

Therefore, what is needed is a modified water cleaning process, which when employed, can reduce or prevent lead precipitation and the associated detrimental effects of lead precipitation.

### BRIEF SUMMARY

An improved method for cleaning semiconductor devices during manufacturing is described. The improved method includes performing cleaning processes on semiconductor wafers having undergone solder bump formation. The cleaning processes generally includes applying deionized water having a temperature of between, for example, about 0 degrees and about 15 degrees Celsius to the semiconductor wafer. The cleaning processes can be applied to the semiconductor wafer at any time during the manufacturing process. For example, the cleaning processes may be applied during or after solder bump formation. Additionally, the cleaning processes may be applied to the whole semiconductor wafer or to singulated semiconductor chips separated from the semiconductor wafer. Still further, the cleaning processes may be applied during singulation processes, such as die-saw processes. Applying cold water to the semiconductor wafer can reduce or prevent undesired lead precipitation from the solder bumps. Accordingly, solder bump oxidation can effectively be avoided.

### BRIEF DESCRIPTION OF THE DRAWINGS

Reference is now made to the following descriptions taken in conjunction with the accompanying drawings.

FIG. 1 illustrates a general block diagram of one embodiment of a process associated with manufacturing semiconductor devices;

FIG. 2 illustrates a semiconductor wafer having a plurality of demarcated semiconductor chips;

FIGS. 3A-3E illustrate elevational views of an exemplary process for forming a solder bump on an individual chip of the semiconductor wafer;

FIG. 4 illustrates a die-saw process for separating singulated semiconductor chips from the semiconductor wafer;

FIG. 5 illustrates a schematic view of a portion of a singulated chip having undesirable lead residue;

FIGS. 6A-C illustrate a schematic depiction of lead migration in water; and

FIG. 7 illustrates a schematic view of a portion of a singulated chip having undergone cleaning processes according to the principles of the present disclosure.

### DETAILED DESCRIPTION

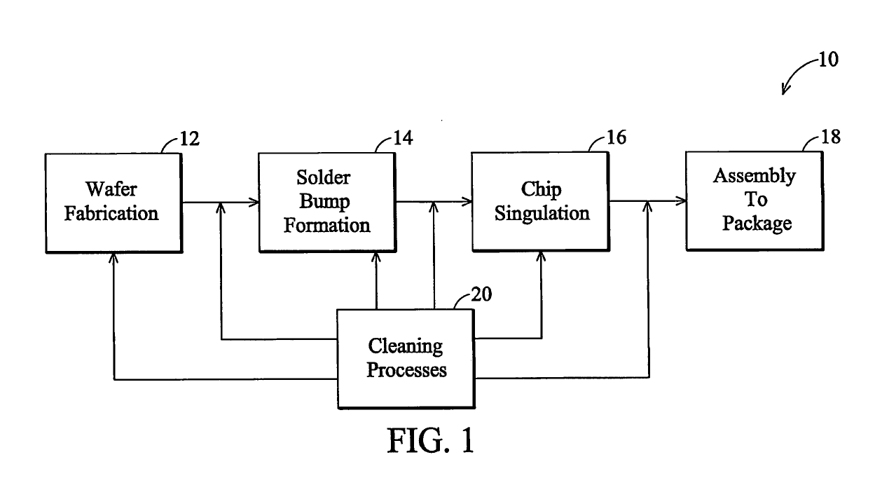

FIG. 1 is a block diagram illustrating an exemplary semiconductor manufacturing process 10 associated with producing chips for use in semiconductor applications. The process 10 includes wafer fabrication 12, which generally involves layering, patterning, doping, and applying heat treatments to a silicon wafer. The process 10 further includes forming solder bumps 14 on the fabricated wafer. The solder bumps generally facilitate electrical and mechanical connection between chip devices singulated from the fabricated wafer and a desired packaging substrate as will be further described. The fabricated wafer is then cut into singulated chips 16 each comprising an entire integrated circuit. After singulation, the chips are assembled 18 with desired packaging to complete the manufacturing process.

The fabricated wafer undergoes a variety of cleaning processes 20 during semiconductor manufacturing. The cleaning processes are applied to generally cleanse the wafer of undesirable particles. The cleaning processes 20 may take place at any time during the semiconductor manufacturing process 10 including before, during, and/or after solder bump formation. Also, the cleaning processes 20 may be applied before, during, and/or after separation of the singulated chip devices from the semiconductor wafer.

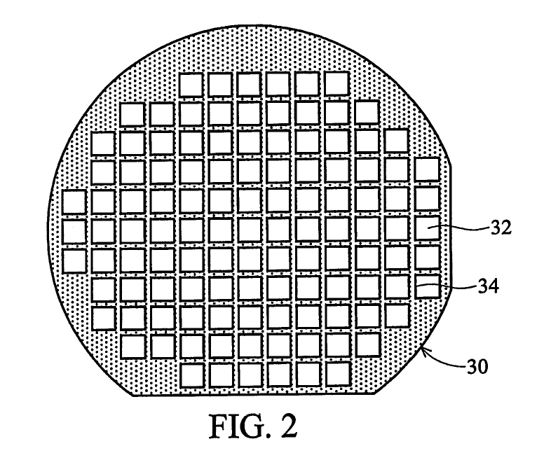

FIG. 2 illustrates a semiconductor wafer 30 (in plan) having a plurality of individual dice, or chips 32, which are demarcated by scribe lines 34. Each chip 32 generally comprises an integrated circuit, which can be adapted into a variety of semiconductor applications. For some applications, such as flip chip applications, it may be desirable to form solder bumps onto the chips 32 to appropriately adapt the chips for use as semiconductor devices.

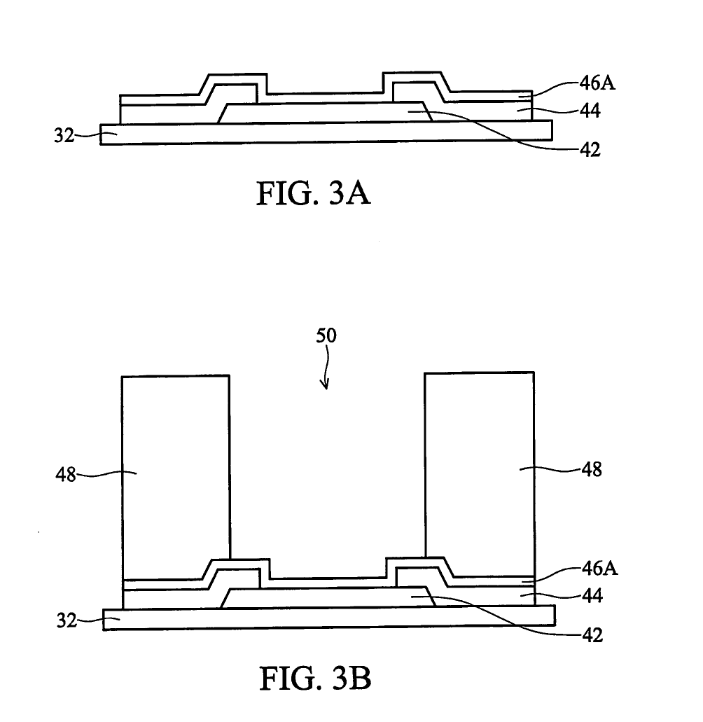

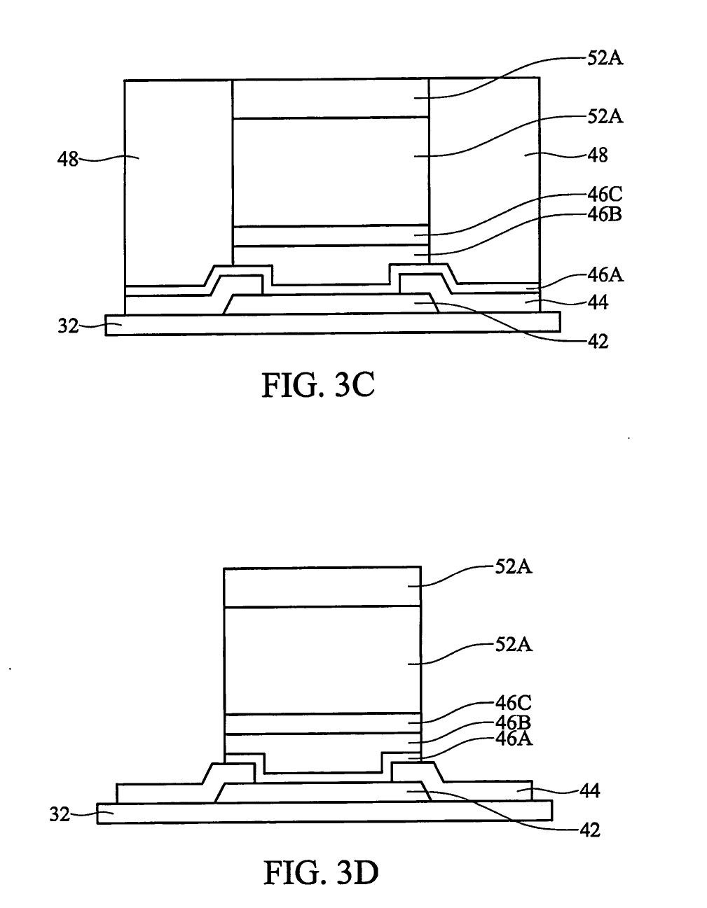

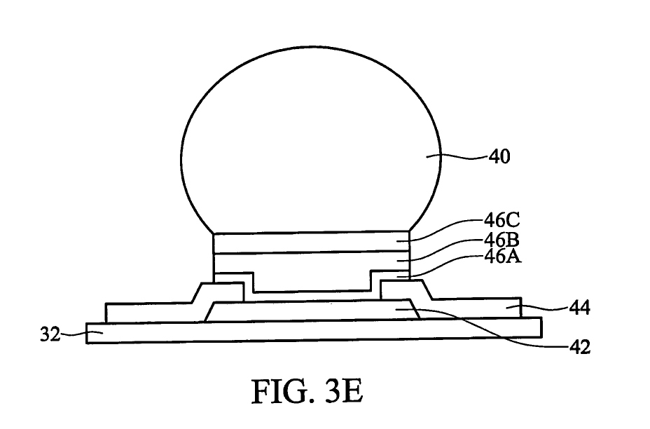

FIGS. 3A-3E illustrate an exemplary process for depositing a solder bump 40 (FIG. 3E) onto a portion of a chip 32 for receiving a solder bump. The solder bump 40 may be formed of a metallic alloy such as a lead-tin alloy. In some embodiments, the solder bump 40 may be formed as part of a larger C4 process (Controlled-Collapse Chip Connection), which connects semiconductor chips, such as chip 32, to substrates in electronic packages. The solder bump 40 may be formed in a variety of manners including vapor deposition of solder material, electro-deposition of solder material, or solder-paste screen-printing. With reference to FIG. 3A, in one embodiment, the chip 32 is prepared to receive the solder bump 40 by first forming a bonding pad 42 on the surface of the semiconductor chip 32. The bonding pad 42 may comprise copper (Cu) or aluminum (Al) and may be vapor deposited onto the semiconductor chip 32. After the bonding pad 42 is formed, a passivation layer 44 of, for example, silicon dioxide (SiO₂) is formed over the semiconductor chip 32 surface excluding a portion overlying the bonding pad 42. One or more under-bump metallization (UBM) layers, e.g., layer 46A, of from about 500 Å to about 5000 521 are then deposited over the bonding pad 42 and a layer of photoresist 48 is additionally formed, as shown in FIG. 3B.

The UBM layer 46A may be, for example, a layer of titanium. The photoresist layer 48 is typically from about 10 to about 25 microns in height. As shown in FIG. 3B, the photoresist layer 48 is photolithographically patterned and developed to form an opening 50 above the bonding pad 42 to expose a UBM layer, e.g., 46A. Referring to FIG. 3C, additional UBM layers, such as 46B and 46C, may be formed within a mask opening 50 by, for example, an electroplating process or vapor deposition process. Layers 46B and 46C may be formed of copper and nickel, respectively. UBM layers are typically formed over the bonding pad 42 to allow for better bonding and wetting of the solder material to the uppermost UBM layer 46C adjacent to the solder material, and for protection of the bonding pad 42 by the lowermost UBM layer 46A. A column of solder material 52A may either be deposited in layers, for example, a layer of lead followed by a layer of tin, where the solder material layers are later formed into a homogeneous solder bump during a reflow (e.g., temporary melting) process for solder material. In other embodiments, the solder material may be deposited as a homogeneous solder material by vapor deposition or electroplating onto a “seed layer,” such as UBM layer 46C.

Referring to FIG. 3D, after removal of the photoresist layer 48, the UBM layer 46A is etched through by an etching process, such as a reactive ion etch (RIE) process, to the underlying passivation layer 44 using the solder column 52A as an etching mask to protect the underlying UBM layers 46A, 46B, and 46C. The solder column 52A is then temporarily heated to a melting point (“reflow”) to form the solder bump 40 over the UBM layer 46C, as shown in FIG. 3E. Completion of the reflow process results in the formation of the homogeneous lead/tin solder bump 40. In some embodiments, the solder bump 40 is a high lead alloy having composition ratios (indicating weight percent) of 95 Pb/5 Sn (95/5) or 90 Pb/10 Sn (90/10) with melting temperatures in excess of 300° C. or eutectic 63 Pb/37 Sn (63/37) with a melting temperature of 183° C. Generally speaking, the resulting solder bump 40 is composed of a homogeneous material and has a well-defined melting temperature. The high melting Pb/Sn alloys are reliable bump metallurgies that are particularly resistant to material fatigue. The above-described process for forming solder bumps is merely exemplary. Accordingly, the solder bump 40 may be formed in a variety of other manners without departing from the scope of the disclosure.

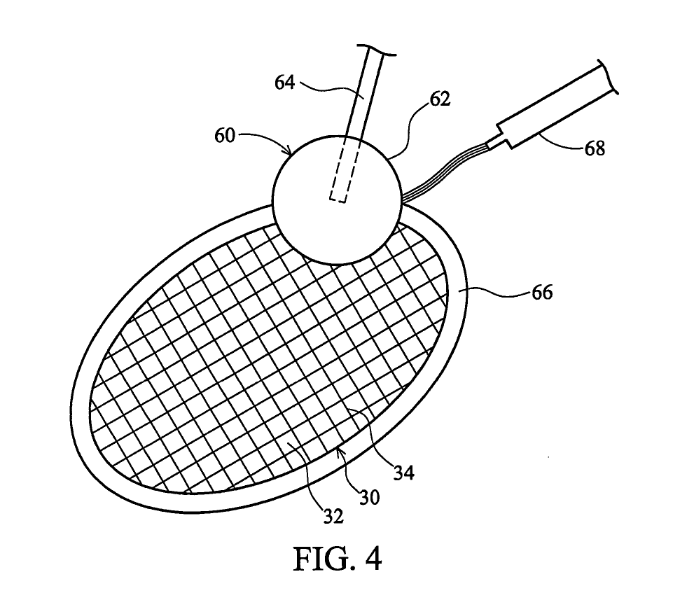

Referring to FIG. 4, the semiconductor wafer 30 additionally undergoes the chip singulation process 16 to separate individual chips 32 from the wafer. In one embodiment, the semiconductor wafer 30 may be singulated via a die-saw 60, which typically includes a blade 62, such as a resin-bonded diamond blade, operable to rotate at high speeds on a spindle 64. The die-saw 60 may be powered in a variety of manners including via electric or pneumatic motors (not shown). In practice, the semiconductor wafer 30 is first mounted onto a dicing tape 66, which retains the individual chips 32 after singulation. Thereafter, the semiconductor wafer 30 with tape 66 is placed onto a mounting chuck (not shown), which is operable to run the wafer under the die-saw 60. The mounting chuck is typically configured to rotate and align the scribe lines 34 of the semiconductor wafer with the die-saw 60 such that the die-saw cuts the wafer along the scribe lines to separate the wafer into singulated chips 32.

Operation of the die-saw 60 generates a considerable amount of heat, which can damage the chips 32 if not appropriately dissipated. Accordingly, in one embodiment, the die-saw 60 may be cooled by water ejected from a water dispensing apparatus, such as a jet nozzle apparatus 68. The water may be applied additionally to cool and cleanse the semiconductor wafer 30 and associated singulated chips 32 during the singulation process.

Semiconductor wafers, such as the semiconductor wafer 30, are often cleaned with deionized (DI) water during the manufacturing process. DI water generally refers to ultra-clean water with very low ionic content. Ionic contaminants in water, such as sodium, iron, or copper can lead to device degradation or failure when deposited onto a wafer surface. One method for measuring ionic content in DI water is by monitoring the DI water resistivity. For example, a water resistivity of about 18×10⁶ ohm-cm or higher generally indicates a low ionic content in DI water. A variety of water purifying measures may be employed to achieve such low ionic content. In some embodiments, water-purifying systems may include several sections of charcoal filters, electrodialysis units, and a number of resin units, which collectively demineralize the water.

The application of DI water may occur at multiple and various times during such manufacturing process. For example, the semiconductor wafer 30 may be cleaned with DI water during the wafer fabrication process 14, such as after any of the deposition and/or etching processes. Additionally, water-cleaning processes may be employed during testing, assembly, and packaging of the semiconductor wafer 30 and chips 32. For example, as described above with respect to the exemplary chip singulation process 16, DI water may be applied to cool the die saw 60 and the associated semiconductor wafer being singulated.

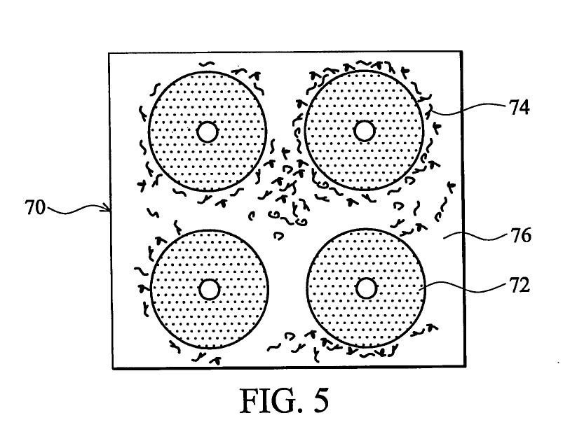

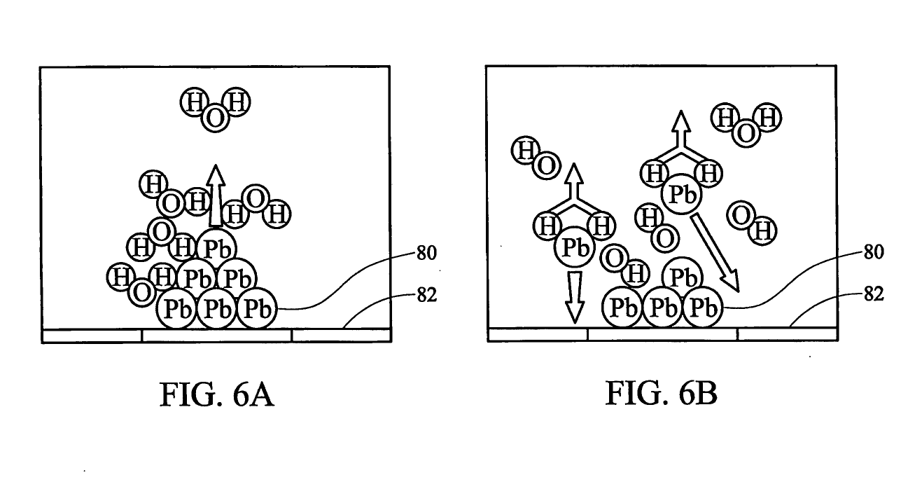

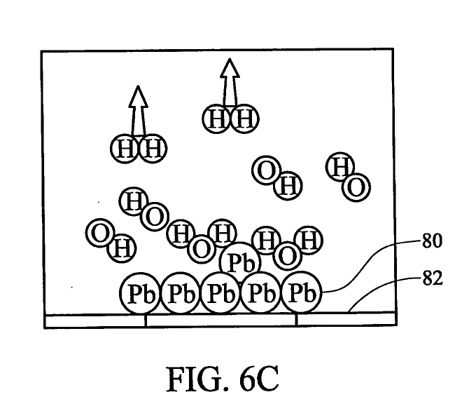

In the past, water having an ambient temperature (e.g. room temperature) has been applied before, during, and after the singulation process. The ambient temperature generally refers to the temperature associated with the ambient surroundings in which wafer processing takes place. It has been found that such water can cause undesirable lead precipitation associated with the solder bumps 40, particularly in those solder bumps having a high lead content indicated by the composition ratio of the solder bumps (e.g. 95 Pb/5 Sn (95/5)). FIG. 5 illustrates a portion of a semiconductor chip 70 having a plurality of solder bumps 72 similar to solder bump 40. The semiconductor chip 70 has undergone conventional water cleaning processes (e.g. ambient temperature water) during semiconductor manufacturing, including during the singulation process 16. The conventional water cleaning processes have caused the lead associated with the solder bumps 40 to precipitate and, upon drying, re-crystallize as lead residue (generally depicted by reference numeral 74) on a surface 76 of the semiconductor chip 70. FIGS. 6A-C illustrate the migration of lead (schematically depicted as Pb particles 80) in water having an ambient temperature. The grouping of lead particles 80 in FIG. 6A generally represents a solder bump 40, which has been deposited onto a surface 82 of a semiconductor wafer 30. As shown progressively in FIGS. 6B and 6C, the lead particles 80 tend to dissolve quickly in ambient-temperature water, thereby resulting in the spreading of such lead particles along the surface 82 of the semiconductor wafer 30.

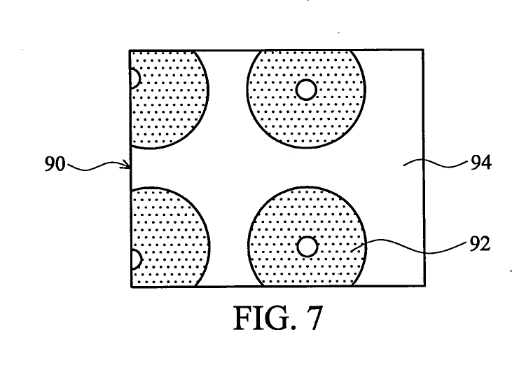

Application of cold water according to the principles of the present disclosure reduces or prevents the precipitation of lead during water cleaning processes. In one embodiment, cold water may be water having a temperature of between about 0 degrees Celsius and about 15 degrees Celsius. In other embodiments, cold water may be defined as any temperature falling below the temperature of the ambient surroundings. FIG. 7 illustrates a portion of a semiconductor chip 90 having a plurality of solder bumps 92. In this embodiment, cold water has been applied to the semiconductor chip 90 during the singulation process. Accordingly, lead in the solder bumps 92 has not precipitated as compared with the semiconductor chip 70, which underwent prior art water cleaning processes. Therefore, after drying, a surface 94 of the semiconductor chip 90 does not include undesired lead residue.

While various methods for reducing lead precipitation according to the principles disclosed herein have been described above, it should be understood that they have been presented by way of example only, and not limitation. Thus, the breadth and scope of the invention(s) should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 CFR 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Brief Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

1. A method for reducing lead precipitation during semiconductor wafer processing, comprising:
providing a semiconductor wafer having a plurality of solder bumps formed thereon, the solder bumps being formed of at least lead;
singulating the semiconductor wafer into a plurality of individual semiconductor chips, the singulation being performed in an environment having an ambient temperature; and
applying deionized water to the semiconductor wafer during singulation, the deionized water having a temperature less than the ambient temperature sufficient to prevent precipitation of the lead in the solder bumps during singulation.

2. The method of claim 1 wherein singulating the semiconductor wafer comprises using a die-saw to cut the wafer.

3. The method of claim 2 wherein the semiconductor wafer includes a plurality of scribe lines to demarcate the semiconductor wafer into a plurality of semiconductor chips, and wherein singulating the semiconductor wafer comprises cutting the semiconductor wafer along the scribe lines.

4. The method of claim 1 wherein applying the deionized water comprises applying deionized water having a temperature of between about 0 and about 15 degrees Celsius.

5. The method of claim 1 wherein applying the deionized water comprises providing a water dispensing apparatus and activating the water dispensing apparatus to dispense the deionized water onto the die-saw.

6. The method of claim 1 wherein applying the deionized water comprises providing a water dispensing apparatus and activating the water dispensing apparatus to dispense the deionized water onto the semiconductor wafer.

7. The method of claim 1 wherein applying the deionized water comprises providing a water dispensing apparatus and activating the water dispensing apparatus to dispense the deionized water onto the die-saw and the semiconductor wafer.

8. The method of claim 1 wherein applying the deionized water comprises applying deionized water having a resistivity of less than about 18×10⁶ ohm-cm.

9. A method for reducing lead precipitation during semiconductor wafer processing, the semiconductor wafer processing being performed in an ambient environment having an ambient temperature, the method comprising:
providing a semiconductor wafer having a plurality of solder bumps formed thereon; and
singulating the semiconductor wafer into a plurality of individual semiconductor chips; and
applying deionized water to the semiconductor wafer before, during, and after singulation, the deionized water having a temperature less than the ambient temperature sufficient to prevent precipitation of the lead in the solder bumps.

10. The method of claim 9 wherein applying deionized water before singulation comprises applying deionized water having a temperature of between about 0 and about 15 degrees Celsius.

11. The method of claim 9 wherein applying deionized water during singulation comprises applying deionized water having a temperature of between about 0 and about 15 degrees Celsius.

12. The method of claim 9 wherein applying deionized water after singulation comprises applying deionized water having a temperature of between about 0 and about 15 degrees Celsius.

13. The method of claim 9 wherein applying deionized water comprises applying deionized water having a resistivity of less than about 18×10⁶ ohm-cm.

14. A method for reducing the amount of lead residue accumulating on a surface of a semiconductor chip during semiconductor manufacturing processes, the semiconductor chip having a plurality of solder bumps, comprising:
processing a semiconductor wafer to separate the semiconductor wafer into a plurality of individual semiconductor chips, the processing taking place in an environment having an ambient temperature; and
applying deionized water to the semiconductor wafer and resulting semiconductor chips during processing thereof, the deionized water having a temperature less than the ambient temperature sufficient to prevent precipitation of the lead in the solder bumps during the processing.

15. The method of claim 14 wherein processing the semiconductor wafer comprises singulating the semiconductor wafer via a die-saw.

16. The method of claim 15 wherein applying deionized water comprises applying deionized water during singulation.

17. The method of claim 14 wherein applying deionized water comprises applying deionized water having a temperature of between about 0 and about 15 degrees Celsius.

18. The method of claim 14 wherein applying deionized water comprises applying deionized water having a resistivity of less than about 18×10⁶ ohm-cm.
